(19) United States
(12) Patent Application Publication
(10) Pub. No.: US 2008/0157316 A1
(43) Pub. Date: Jul. 3, 2008

(54) Multi-chips package and method of forming the same

(75) Inventor: Wen-Kun Yang, Hsin-Chu City (TW)

Correspondence Address: BIRCH STEWART KOLASCH & BIRCH, PO BOX 747, FALLS CHURCH, VA, 22040-0747, US

(73) Assignee: Advanced Chip Engineering Technology Inc.

(21) Appl. No.: 11/648,797

(22) Filed: Jan. 3, 2007

(51) Int. Cl. H01L 23/02

(52) U.S. Cl. 257/685

(57) ABSTRACT

The present invention provides a structure of multi-chips package comprising: a substrate with a die receiving cavity formed within an upper surface of the substrate and a first through holes structure, wherein terminal pads are formed under the first through holes structure. A first die is disposed within the die receiving cavity and a first dielectric layer is formed on the first die and the substrate. A first re-distribution conductive layer (RDL) is formed on the first dielectric layer. A second dielectric layer is formed over the first RDL. A third dielectric layer is formed under a second die. A second re-distribution conductive layer (RDL) is formed under the third dielectric layer. A fourth dielectric layer is formed under the second RDL. Conductive bumps are coupled to the first RDL and the second RDL. A surrounding material surrounds the second die. The second die is coupled to the first die through the first RDL, second RDL and the conductive bumps.

### FIELD OF THE INVENTION

This invention relates to a structure for system in Package (SIP), and more particularly to a panel scale package (PSP) with SIP.

### DESCRIPTION OF THE PRIOR ART

In the field of semiconductor devices, the device density is increased and the device dimension is reduced, continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support. As a semiconductor become more complicated, the traditional package technique, for example lead frame package, flex package, rigid package technique, can't meet the demand of producing smaller chip with high density elements on the chip.

Currently, multi-chip modules and hybrid circuits are typically mounted on a substrate and the components are typically sealed within a casing. It is common to utilize a multilayer substrate comprised of multiple layers of conductors sandwiched between multiple layers of dielectric material. Multilayer substrates are conventionally fabricated by lamination techniques in which metal conductors are formed on individual dielectric layers, and the dielectric layers are then stacked and bonded together.

The requirement of high density, high performance speeds up the developments of System On Chip (SOC) and System In a Package (SIP). Multi-Chip Module (MCM) is widely used to integrate chips having different functions. Multi-chip package (MCP) or multi-chip module (MCM) technology refers to the practice of mounting multiple, unpackaged integrated circuits (IC's) (“bare die”) on a base material. The multiple dice are “packaged” within an overall encapsulation material or other polymer. MCM provides a high density module that requires less space on the motherboard of a computer. The MCM also provides the benefit of integrated functional testing.

Furthermore, because conventional package technologies have to divide a dice on a wafer into respective dies and then package the die respectively, therefore, these techniques are time consuming for manufacture process. Since the chip package technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is to be understood as meaning that the entire packaging and all the interconnections on the wafer as well as other processing steps are carried out before the singulating (dicing) into chips (dice). Generally, after completion of all assembling processes or packaging processes, individual semiconductor packages are separated from a wafer having a plurality of semiconductor dies. The wafer level package has extremely small dimensions combined with extremely good electrical properties. WLP technique is an advanced packaging technology, by which the dice are manufactured and tested on the wafer, and then singulated by dicing for assembly in a surface mounting line. Because the wafer level package technique utilizes the whole wafer as one object, not utilizing a single chip or die, therefore, before performing a scribing process, packaging and testing has been accomplished; furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices.

Though the advantages of WLP technique mentioned above, some issues still exist influencing the acceptance of WLP technique. For example, although utilizing WLP technique can reduce the CTE mismatch between IC and the interconnecting substrate (build up layers—RDL), but it can not allow the higher ball count in the size of chip. As the size of the device minimizes, the number of terminal pads has been limited. Furthermore, in this wafer-level chip-scale package, a plurality of bond pads formed on the semiconductor die is redistributed through conventional redistribution processes involving a redistribution layer (RDL) into a plurality of metal pads in an area array type. Solder balls are directly fused on the metal pads, which are formed in the area array type by means of the redistribution process. Typically, all of the stacked redistribution layers are formed over the built-up layer over the die. Therefore, the thickness of the package is increased. This may conflict with the demand of reducing the size of a chip. Therefore, the present invention provides a multi-chips package for fan-out WLP (panel wafer) with stacking and side by side structure.

### SUMMARY OF THE INVENTION

One aspect of the present invention is to provide a SIP with higher reliability, lower cost advantages.

The present invention provides a structure of multi-chips package comprising: a substrate with a die receiving cavity formed within an upper surface of said substrate and a through holes structure formed there through, wherein a wiring circuit with terminal pad is formed under the through holes structure. A first die is disposed (attached) within the die receiving cavity. A first dielectric layer is formed on the first die and the substrate and filled into the gap between the die edge and side wall of the cavity. A first re-distribution conductive layer (RDL) is formed on the first dielectric layer, wherein the first RDL is coupled to the first die and the terminal pad through the through holes structure. A second dielectric layer is formed over the first RDL to expose the contact pads (includes UBM structure—does not show in the drawing). A second die is provided. A third dielectric layer is formed under the second die (on the active surface side). A second re-distribution conductive layer (RDL) is formed under the third dielectric layer, wherein the second RDL is coupled to the second die. A fourth dielectric layer is formed under the second RDL to expose the contact pads (includes UBM structure—does not show in the drawing). Conductive bumps are formed between the first die and the second die to couple the contact pads of first RDL and the contact pads of second RDL. A surrounding material surrounds the second die which can be as optional structure.

The first RDL fans out from the first dice and couples the electrical signal from the metal (Al) pads of the first die to the terminal pads through the metal of through holes of the substrate.

The second die of above structure can be made by silicon wafer level packaging process (WLP) to have the build up layers (second RDL) and conductive bump built before dicing saw. After the dicing saw, to use the flip chip mounting method mounts the second die (WLP-CSP) on the processed panel wafer (with first RDL and contact pads—includes the UBM structure).

Alternatively, the structure of multi-chips package comprises a substrate with at least two dice receiving cavities formed within an upper surface of the substrate to receive at least two dice and through hole structures formed there through, wherein wiring circuits with terminal pads are formed under the through hole structures. A first die and a second die are disposed (attached) within the at least two die receiving cavities, respectively. A first dielectric layer is formed on the first die, second die and the substrate, and filled the gap between the die edge and side wall of the cavity. A first re-distribution conductive layer (RDL) is formed on the first dielectric layer, wherein the first RDL is coupled to the first die, second die and the terminal pads through the through holes structure. A second dielectric layer is formed over the first RDL to expose the contact pads (includes the UBM structure—does not show in the drawing). A third die is provided. A third dielectric layer is formed under the third die (on the active surface side). A second re-distribution conductive layer (RDL) is formed under the third dielectric layer, wherein the second RDL is coupled to the third die. A fourth dielectric layer is formed under the second RDL to expose the contact pads (includes the UBM structure—does not show in the drawing). Conductive bumps are formed between the first die and/or the second die and the third die to couple the first RDL and second RDL. Further, a surrounding material surrounds the third die which can be as optional structure.

The third die of above structure can be made by silicon wafer level packaging process (WLP) to have the build up layers (second RDL) and conductive bump built before dicing saw. After the dicing saw, to use the flip chip mounting method mounts the second die (WLP-CSP) on the processed panel wafer (with first RDL and contact pads—includes the UBM structure).

The first dielectric layer includes an elastic dielectric layer. Alternatively, the first and second dielectric layers comprise a silicone dielectric based material, BCB or PI, wherein the silicone dielectric based material comprises siloxane polymers (SINR), Dow Corning WL5000 series, or composites thereof. The first and second dielectric layers may comprise a photosensitive (photo-patternable) layer.

The material of the substrate includes epoxy type FR5, FR4, BT, PCB (print circuit board), alloy, glass, silicon, ceramic or metal. Alternatively, the material of the substrate includes Alloy42 (42% Ni-58% Fe) or Kovar (29% Ni-17% Co-54% Fe).

Furthermore, the present invention provides a method for forming semiconductor device package, comprising providing a substrate with a die receiving cavities formed within an upper surface of the substrate and a through holes structure formed there through, wherein wiring circuit with terminal pads are formed under the through hole. Next, at least one first die is redistributed on a tool with a desired pitch using a pick and place fine alignment system. Adhesive material is attached on the at least first die back side. And then, the substrate is bonded (under vacuum condition) to the die back side, and the die within the cavity of substrate, and separating the panel away from tool. Subsequently, a first dielectric layer is coated on the first die and the substrate, and filled into the gap between the die edge and side wall of the cavity. A first RDL is then formed on the first dielectric layer. Next, a second dielectric layer is formed over the first RDL, and exposed the contact pads and built up the UBM structure. A second die is provided. And a third dielectric layer is formed under the second die (on the active surface side). A second RDL is then formed under the third dielectric layer. Subsequently, forth dielectric layer is formed under the second RDL to form the contact metal pads (includes UBM process) and to protect the second RDL. Conductive bumps are formed between the first die and the second die to couple the first RDL and the second RDL. Finally, a surrounding material is formed to surround the second die which can be as an optional process.

The method for forming a second die of above process comprises a silicon wafer with second die.

### BRIEF DESCRIPTION OF THE DRAWINGS

FIG. 1 illustrates a cross-sectional view of a structure of stacked fan-out SIP according to the present invention.

FIG. 2 illustrates a cross-sectional view of a structure of parallel (side-by-side) fan-out SIP according to the present invention.

FIG. 3 illustrates a cross-sectional view of a structure of stacked fan-out SIP according to the present invention.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying Claims.

The present invention discloses a structure of WLP utilizing a substrate having predetermined circuit with through holes formed therein and a cavity formed into the substrate. A photosensitive material is coated over the die and the pre-formed substrate. Preferably, the material of the photosensitive material is formed of elastic material.

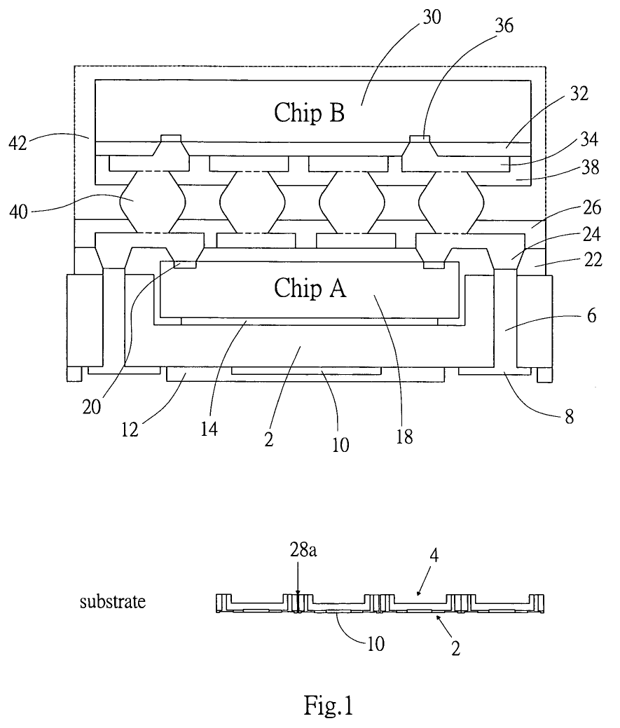

FIG. 1 illustrates a cross-sectional view of panel scale package (PSP) for system in package (SIP) in accordance with one embodiment of the present invention. As shown in the FIG. 1, the structure of SIP includes a substrate 2 having a die receiving cavity 4 formed therein to receive a die 18. The substrate 2 could be round type such as wafer type, the diameter could be 200, 300 mm or higher. It could be employed for rectangular type such as panel form. FIG. 1 illustrates the pre-formed substrate 2 in cross section. A scribe line 28a is the cutting point or area of a wafer level package. As can be seen from the drawings, the substrates 2 are formed with cavities 4 and built in circuit 10, the through holes structure 6 with metal filled therein. Pluralities of through holes 6 are created through the substrate 2 from upper surface to lower surface of the substrate 2. A conductive material will be re-filled into the through holes 6 for electrical communication. Terminal pads 8 are located on the lower surface of the substrate and connected to the through holes 6 with conductive material. A conductive circuit trace 10 is configured on the lower surface of the substrate 2. A protective layer 12, for instance solder mask epoxy, is formed over the conductive trace 10 for protection.

The die 18 is disposed within the die receiving cavity 4 on the substrate 2 and fixed by an adhesion (die attached) material 14. As know, contact pads (metal bonding pads) 20 are formed on the die 18. A photosensitive layer or dielectric layer 22 is formed over the die 18 and filling into the space between the die 18 and the side walls of the cavity 4. Pluralities of openings are formed within the dielectric layer 22 through the lithography process or exposure and development procedure. The pluralities of openings are aligned to the contact via through holes 6 and the contact or I/O pads 20 of the die 18, respectively. The RDL (re-distribution layer) 24, also referred to as conductive trace 24, is formed on the dielectric layer 22 by removing selected portions of layer formed over the layer 22, wherein the RDL 24 keeps electrically connected with the die 18 through the I/O pads 20. A part of the material of the RDL will re-fills into the openings in the dielectric layer 22, thereby forming contact via metal over the through holes 6 and pad metal over the bonding pad 20. A dielectric layer 26 is formed to cover the RDL 24. The dielectric layer 26 is formed atop of the die 18 and substrate 2 and the dielectric layer 22. Pluralities of openings are formed within the dielectric layer 26 and aligned to the RDL 24 to expose portion of the RDL 24.

A second chip 30 has second pads 36 formed therein. Dielectric material 32 is formed (coated) over a surface of the chip 30 to expose die pads 36 of the chip 30. A seed metal layers and second redistributed conductive layer 34 are formed over the dielectric layer 32 to connect to the die pads 36. The redistributed conductive layer 34 is to as a conductive connection of the chip 30. Another dielectric material 38 having openings is formed (coated) over the redistributed conductive layer 34 to expose contact pads (soldering balls contact) of the redistributed conductive layer 34 and protect the chip 30. The openings are created by using the conventional manner and aligned to the redistributed conductive layer 34. The Under Bump Metallurgy (UBM) is formed on the contact pads opening. Conductive (soldering) bumps 40 are coupled to the RDL 24 and RDL 34. The structure with terminal pads 8 refers to the LGA type SIP (system in package) or SIP-LGA. If the conductive bumps are added, it refers to the BGA (Ball Grid Array) type SIP (system in package) or SIP-BGA. It is noted that the surfaces having pads of the dual dice are face to face with each other.

A protection layer 42 is formed over the second chip 30 and the conductive bumps 40. The material for the protection layer 42 could be epoxy, rubber, resin, plastic, ceramic and so on.

It should be noted that the first chip 18 may communicate with the second chip 30 through the conductive bumps 40, first RDL 24, second RDL 38. The arrangement is optional. As can be found, the first chip 18 is formed within a cavity 4 to reduce the height of the entire SIP. The first RDL configuration is Fan-Out type to increase the ball pitch, thereby increasing the reliability and thermal dispassion.

Preferably, the material of the substrate 2 is organic substrate likes epoxy type FR5, BT (Bismaleimide triazine), PCB with defined cavity or metal, Alloy42 with pre etching circuit. The organic substrate with high Glass transition temperature (Tg) are epoxy type FR5 or BT (Bismaleimide triazine) type substrate are preferred due to the curing temperature of dielectric materials which can not be higher than Tg of substrate 2 to prevent the properties of substrate be changed. The Alloy42 is composed of 42% Ni and 58% Fe. Kovar can be used also, and it is composed of 29% Ni, 17% Co, 54% Fe. The metal Copper (Cu) can be used too. The glass, ceramic, silicon can be used as the substrate due to lower CTE.

In one embodiment of the present invention, the dielectric layer 22 is preferably an elastic dielectric material which is made by silicone dielectric based materials comprising siloxane polymers (SINR), Dow Corning WL5000 series, and composites thereof, and the elastic materials can be used as releasing buffer of thermal mechanical stress. In another embodiment, the dielectric layer is made by a material comprising polyimides (PI) or silicone resin. Preferably, it is a photosensitive layer for simple process.

In one embodiment of the present invention, the elastic dielectric layer 22 is a kind of material with CTE larger than 100 (ppm/° C.), elongation rate about 40 percent (preferably 30 percent-50 percent), and the hardness of the material is between plastic and rubber. The thickness of the elastic dielectric layer 22 depends on the stress accumulated in the RDL/dielectric layer interface during temperature cycling test.

In one embodiment of the invention, the material of the RDL 24, 34 comprises Ti/Cu/Au alloy or Ti/Cu/Ni/Au alloy; the thickness of the RDL 24 is between 2 um and 15 um. The Ti/Cu alloy is formed by sputtering technique also as seed metal layer, and the Cu/Au or Cu/Ni/Au alloy is formed by electroplating; exploiting the electro-plating process to form the RDL can make the RDL thick enough to withstand CTE mismatching during temperature cycling. The metal pads 20, 36 can be Al or Cu or combination thereof. If the structure of FO-WLP utilizes SINR as the elastic dielectric layer and Cu as the RDL metal, the stress accumulated in the RDL/dielectric layer interface is reduced.

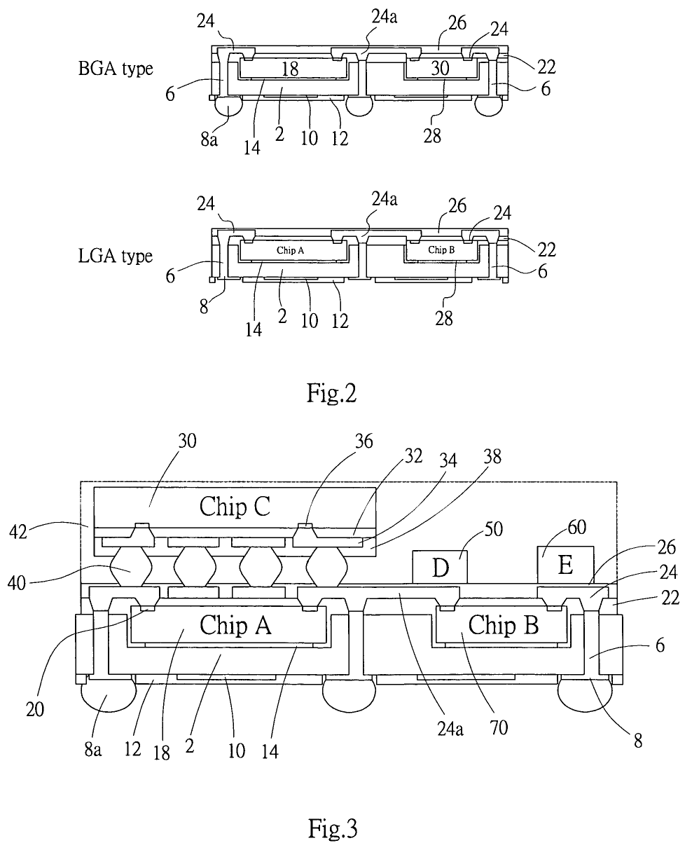

Please refer to FIG. 2, the first chip 18 and the second chip 30 are disposed within the die receiving cavity 4 with different size on the substrate 2 and fixed by an adhesion (die attached) material 14 and 28, respectively. In the upper portion of FIG. 2, the first chip 18 and the second chip 30 are not arranged in stacked configuration. The second chip 30 is locates adjacent to the first chip 18 and both chips are communicated with each other via a horizontal communication line 24a instead of through hole structure. As can be seen, the substrate includes at least two cavities to receive first and second chips, respectively. The BGA with conductive bumps 8a and LGA type with terminal pads 8 are shown in the illustration, respectively. If the conductive bumps are omitted, it refers to LGA type SIP (system in package) or SIP-LGA. The other parts are similar to FIG. 1, and therefore, the reference numbers of the similar parts are omitted.

Alternatively, the embodiment of FIG. 3 combines the aspects of the FIGS. 1 and 2. At least three chips are arranged in the SIP. The upper layer chips 30 may communicates with the chip 18 through RDL 24, 34 and conductive bumps 40. The lower layer chips 18 and 70 may be coupled via RDL 24a, and the upper layer passive components 50 and 60 may communicate with the lower layer chip 70 via RDL 24, 24a.

The upper layer chips 30 with build up layers and solder bumps can be made by wafer level packaging process before dicing saw the wafer (Post wafer process), and it is the wafer level chip size packaging (WLP-CSP) structure and process. The upper layer chips 30 can be flip chip mounting method on the lower layer chips (processed panel wafer) by flip chip bonder, and the passive components 50 and 60 also can be mounted and IR re-flow to solder join with lower layer chips by SMT (surface mount Technology) process.

A protection layer 42 is formed over to cover the second chip 30, the passive components 50, 60 and the conductive bumps 40 as optional structure. The material for the protection layer 42 could be epoxy, rubber, resin, plastic, ceramic and so on. As shown in FIGS. 1-3, the RDLs 24, 24a fan out of the dice and they communicate downwardly toward the terminal pads 8 under the package through holes structure. It is different from the prior art MCP technology which stacks layers over the die, thereby increasing the thickness of the package. However, it violates the rule to reduce the die package thickness. On the contrary, the terminal pads are located on the surface that is opposite to the die pads side. The communication traces are penetrates through the substrate 2 via the through holes and leads the signal to the terminal pad 8. Therefore, the thickness of the die package is apparently shrinkage. The package of the present invention will be thinner than the prior art. Further, the substrate is pre-prepared before package. The cavity 4 and the wiring circuit 10 are pre-determined as well. Thus, the throughput will be improved than ever. The present invention discloses a fan-out WLP without stacked built-up layers over the RDL.

After the wafer is processed and back-lapped to a desired thickness, the wafer is divided into dice. The substrate is pre-formed with the build in circuit therein and at least one type size cavity. Preferably, the material for substrate is FR5/BT print circuit board with higher Tg (Glass transition temperature) property. The substrate may have cavities with different size (for example, equal to die size plus ˜100 um/side) to receive different chips, and the depth of the cavities is deeper than the thickness of dice thickness around 20 um to 30 um for die attached material. The inter-connect pads can be re-distributed to properly area to relax the pitch dimension for better yield.

The process for the present invention includes providing an alignment tool (plate) with alignment pattern formed thereon. Then, the pattern glues is printed on the tool (be used for sticking the surface of dice), followed by using pick and place fine alignment system with flip chip function to re-distribute the known good dies on the tool with desired pitch. The pattern glues will stick the chips on the tool. Subsequently, the die attached materials is printed on the die back side. Then, the vacuum panel bonder is used to bond the substrate on to die back side; the upper surface of substrate except the cavities also be stuck on the pattern glues, then vacuum curing the die attached material, and then separating the tool with panel wafer (Panel wafer means the die be attached on the cavity of substrate). The die attached materials is thermally cured to ensure the die is attached on the substrate.

Alternatively, the die bonder machine with fine alignment is employed, and the die attached materials is dispensed on the cavity of the substrate. The die is placed onto the cavity of substrate. That is, flip chip the upper layer chip is place onto the processed panel wafer (lower layer chips with build up layers), and then reflow to soldering flip chip and/or passive components mounting on the processed panel wafer. The upper layer chip (die) has been processed as flip chip bump structure (WLP-CSP).

Once the die is re-distributed on the substrate, then, a clean up procedure is performed to clean the dice surface by wet and/or dry clean. Next step is to coat the dielectric materials on the panel surface, followed by performing vacuum procedure to ensure there is no bubble within the panel. Subsequently, lithography process is performed to open contact via and metal (Al) bonding pads and/or scribe line. Plasma clean step is then executed to clean the surface of via holes and metal (Al) bonding pads. Next step is to sputter Ti/Cu as seed metal layers, and then Photo Resistor (PR) is coated over the dielectric layer and seed metal layers for forming the patterns of redistributed metal layers (RDL). Then, the electro plating is processed to form Cu/Au or Cu/Ni/Au as the RDL metal, followed by stripping the PR and wet etching metal to form the RDL metal trace. Subsequently, the next step is to coat or print the top dielectric layer and open the contact metal pads of solder bump and/or the scribe line, thereby completing the first layer panel process.

The next procedure could be repeated the above mentioned steps to form multi-layers metal and dielectric layers to complete the second layer dice. Sputtering Ti/Cu step is performed to form the seed metal layers, and coating PR to form the RDL pattern. Then, electro plating step is used to form Cu/Au into RDL pattern, then, stripping the PR and wet etching seed metal to form second RDL metal trace. A top dielectric layer is formed to protect the second RDL trace.

Preferably, the thinner die (around 50 um-127 um) can get better performance of process and reliability. The process further includes mounting the upper layer chips (CSP) by flip chip bonder. After the upper layer chip (CSP) is mounted, the heat re-flow procedure is performed to re-flow, and then, conductive (soldering) bumps (balls) coupled to the first RDL and second RDL.

The testing is executed. Panel wafer level final testing is performed by using vertical probe card. After the testing, the substrate is sawed to singulate the package into individual SIP units with multi-chips. Then, the packages are respectively picked and placed the package (device) on the tray or tape and reel.

The advantages of the present invention are:

The substrate is pre-prepared with pre-form cavities; the size of cavity equal to die size plus around 50 um to 100 um per/side; it can be used as stress buffer releasing area by filling the elastic dielectric materials to absorb the thermal mechanical stress due to the CTE difference between silicon die and substrate (FR5/BT). The SIP packaging throughput will be increased (manufacturing cycle time was reduced) due to apply the simple build up layers on top the surface of die and substrate. The wiring circuits with terminal pads are formed on the opposite surface to the dice active surface (preformed). The dice placement process is the same as the current process. No core paste (resin, epoxy compound, silicone rubber, etc.) filling is necessary for the present invention. There is no CTE mismatching issue once solder join with mother board PCB. The deepness between die and substrate FR4 is only around 20 um˜30 um (be used for thickness of die attached materials), the surface level of die and substrate can be the same after die is attached on the cavities of substrate for build up layers process. Only silicone dielectric material (preferably SINR) is coated on the active surface and the substrate (preferably FR45 or BT) surface. The contacting via structure is opened by using photo mask process only due to the dielectric layer (SINR) is photosensitive layer for opening the contacting via. Vacuum process during SINR coating is used to eliminate the bubble issue. The die attached material is printed on the back-side of dice before substrate be bonded together with dice (chips). The reliability for both package and board level is better than ever, especially, for the board level temperature cycling test, it was due to the CTE of substrate and PCB mother board are identical, so, no thermal mechanical stress be applied on the solder bumps/balls. The cost is low and the process is simple. It is easy to form the combo package (multi chips package).

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. A structure of multi-chips package, comprising:
a substrate with a die receiving cavity formed within an upper surface of said substrate and a through hole structure formed there through, wherein a wiring circuit with terminal pad is formed under said through hole structure;
a first die disposed within said die receiving cavity;
a first dielectric layer formed on said first die and said substrate;
a first re-distribution conductive layer (RDL) formed on said first dielectric layer, wherein said first RDL is coupled to said first die and said terminal pad through said through hole structure;
a second dielectric layer formed over said first RDL;
a second die;
a third dielectric layer formed under said second die;
a second re-distribution conductive layer (RDL) formed under said third dielectric layer, wherein said second RDL is coupled to said second die;
a fourth dielectric layer formed under said second RDL; and
conductive bumps formed between said first die and said second die to couple said first RDL and said second RDL.

2. The structure of claim 1, wherein said first dielectric layer includes an elastic dielectric layer.

3. The structure of claim 1, wherein said first and said second dielectric layer comprise a silicone dielectric based material, BCB or PI, wherein said silicone dielectric based material comprises siloxane polymers (SINR), Dow Corning WL5000 series, or combination thereof.

4. The structure of claim 1, wherein said first and said second dielectric layer comprise a photosensitive (photo patternable) layer.

5. The structure of claim 1, wherein said first or second RDL is made from an alloy comprising Ti/Cu/Au alloy or Ti/Cu/Ni/Au alloy.

6. The structure of claim 1, wherein said first RDL fans out from said first die.

7. The structure of claim 1, wherein the material of said substrate includes epoxy type FR5, FR4, BT, PCB (print circuit board), alloy, glass, silicon, ceramic or metal.

8. The structure of claim 1, further comprising a surrounding material formed surrounding said second die.

9. A structure of multi-chips package, comprising:
a substrate with at least two dice receiving cavities formed within an upper surface of said substrate to receive at least two dice and through hole structures formed there through, wherein wiring circuits with terminal pads are formed under said through hole structures;
a first die and a second die disposed within said at least two die receiving cavities, respectively;
a first dielectric layer formed on said first die, said second die and said substrate;
a first re-distribution conductive layer (RDL) formed on said first dielectric layer, wherein said first RDL is coupled to said first die, said second die and said terminal pads through said through hole structure;
a second dielectric layer formed over said first RDL.
a third die;
a third dielectric layer formed under said third die;
a second re-distribution conductive layer (RDL) formed under said third dielectric layer, wherein said second RDL is coupled to said third die;
a fourth dielectric layer formed under said second RDL; and
conductive bumps formed between said first die and said third die to couple said first RDL and said second RDL.

10. The structure of claim 9, wherein said first dielectric layer includes an elastic dielectric layer.

11. The structure of claim 9, wherein said first and said second dielectric layer comprise a silicone dielectric based material, BCB or PI, wherein said silicone dielectric based material comprises siloxane polymers (SINR), Dow Corning WL5000 series or composites thereof.

12. The structure of claim 9, wherein said first and said second dielectric layers comprise a photosensitive (photo patternable) layer.

13. The structure of claim 9, wherein said first RDL is made from an alloy comprising Ti/Cu/Au alloy or Ti/Cu/Ni/Au alloy.

14. The structure of claim 9, wherein said first RDL fans out from said first die and said second die.

15. The structure of claim 9, wherein said first die and said second die communicates with each other through said first RDL.

16. The structure of claim 9, wherein the material of said substrate includes epoxy type FR5, FR4, BT, PCB (print circuit board), alloy, glass, silicon, ceramic or metal.

17. The structure of claim 9, wherein said second RDL is made from an alloy comprising Ti/Cu/Au alloy or Ti/Cu/Ni/Au alloy.

18. The structure of claim 9, further comprising at least one passive component mounted and connecting to said contact pads of first RDL.

19. The structure of claim 9, further comprising a surrounding material formed surrounding said third die and/or passive components.

20. A method for forming semiconductor device package, comprising:
providing a substrate with a die receiving cavity formed within an upper surface of said substrate and a through hole structure formed there through, wherein wiring circuit with terminal pads are formed under said through hole;
redistributing at least one first die on a tool with a desired pitch using a pick and place fine alignment system;
attaching adhesive material on said at least first die back side;
bonding said substrate to said die back side, and said die disposed on said cavity of said substrate, and separating said tool to form panel wafer;
coating a first dielectric layer on at least said first die and said substrate, and filling into the gap between said die edge and side wall of said cavity;
forming a first RDL on said first dielectric layer;
forming a second dielectric layer over said first RDL to expose first contact pads;
providing a second die;
forming a third dielectric layer under said second die;
forming a second RDL under said third dielectric layer;
forming a forth dielectric layer under said second RDL to protect said second RDL to expose second contact pads; and
forming conductive bumps between said first die and said second die to couple said first contact pads of said first RDL and said second contact pads of said second RDL.

21. The method of claim 20, wherein said first and said second dielectric layer comprise a silicone dielectric based material, BCB or PI, wherein said silicone dielectric based material comprises siloxane polymers (SINR), Dow Corning WL5000 series, or composites thereof.

22. The method of claim 20, wherein said first and said second dielectric layers comprise a photosensitive (photo patternable) layer.

23. The method of claim 20, wherein said first and said second RDL are made from an alloy comprising Ti/Cu/Au alloy or Ti/Cu/Ni/Au alloy.

24. The method of claim 20, wherein the material of said substrate includes epoxy type FR5, FR4, BT, PCB (print circuit board), alloy, glass, silicon, ceramic or metal.

25. The method of claim 20, further comprising a step to form a surrounding material to surround said second die.

26. The method of claim 20, wherein said second die is produced by wafer level packaging (WLP) process with build up layers (RDL) and soldering bumps/balls on top of the die surface, then, using flip chip mounting method attached said second die (WLP-CSP) on the processed panel wafer, to re-flow the solder bumps/balls for coupling said first contact pads of said first RDL and said second contact pads of said second RDL.
